(19) United States
(12) Patent Application Publication
(10) Pub. No.: US 2026/0362592 A1
(43) Pub. Date: Nov. 12, 2026

(54) WIRING SUBSTRATE

(71) Applicant: IBIDEN CO., LTD., Gifu (JP)

(72) Inventors: Kotaro TAKAGI, Gifu (JP); Yui KUNISHIMA, Gifu (JP); Shigeto IYODA, Gifu (JP)

(73) Assignee: IBIDEN CO., LTD., Gifu (JP)

(21) Appl. No.: 19/396,536

(22) Filed: Nov. 21, 2025

(30) Foreign Application Priority Data
Dec. 5, 2024 (JP) 2024-212041

(51) Int. Cl. H05K 1/02; H05K 1/185

(52) U.S. Cl. CPC H05K 1/0298; H05K 1/185

(57) ABSTRACT

A wiring substrate includes a multilayer core substrate including a central insulating layer, a first-surface-side insulating layer, and a second-surface-side insulating layer, a build-up layer formed on the first-surface-side insulating layer, and a component accommodated in the first-surface-side insulating layer. The first-surface-side insulating layer includes insulating layers on a first-surface side of the central insulating layer. The second-surface-side insulating layer includes insulating layers on a second-surface side of the central insulating layer. The multilayer core substrate includes a first inner-layer conductor layer, a second inner-layer conductor layer, a first surface-layer conductor layer formed on an outermost layer of the first-surface-side insulating layer, a second surface-layer conductor layer formed on an outermost layer of the second-surface-side insulating layer, and a through hole formed between the first surface-layer and second surface-layer conductor layers such that the through hole is connected to the first inner-layer conductor layer and the second inner-layer conductor layer.

### CROSS-REFERENCE TO RELATED APPLICATIONS

The present application is based upon and claims the benefit of priority to Japanese Patent Application No. 2024-212041, filed Dec. 5, 2024, the entire contents of which are incorporated herein by reference.

### BACKGROUND OF THE INVENTION

### Field of the Invention

The present invention relates to a wiring substrate.

### Description of Background Art

International Publication No. 2001/19148 describes a wiring board that includes a multilayer core substrate with through holes formed therein and build-up wiring layers formed on both surfaces of the multilayer core substrate. The entire contents of this publication are incorporated herein by reference.

### SUMMARY OF THE INVENTION

According to one aspect of the present invention, a wiring substrate includes a multilayer core substrate including a central insulating layer, a first-surface-side insulating layer, and a second-surface-side insulating layer, a build-up layer formed on the multilayer core substrate such that the build-up layer is positioned on the first-surface-side insulating layer of the multilayer core substrate, and a component accommodated in the multilayer core substrate such that the component is positioned in the first-surface-side insulating layer of the multilayer core substrate. The multilayer core substrate is formed such that the first-surface-side insulating layer includes insulating layers on a first-surface side of the central insulating layer and that the second-surface-side insulating layer includes insulating layers on a second-surface side of the central insulating layer, and the multilayer core substrate includes conductor layers including a first inner-layer conductor layer formed on a first surface of the central insulating layer, a second inner-layer conductor layer on a second surface of the central insulating layer, a first surface-layer conductor layer formed on an outermost layer of the first-surface-side insulating layer, a second surface-layer conductor layer formed on an outermost layer of the second-surface-side insulating layer, and a through hole formed between the first surface-layer conductor layer and the second surface-layer conductor layer such that the through hole is connected to the first inner-layer conductor layer and the second inner-layer conductor layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a wiring substrate according to an embodiment of the present invention;

FIG. 2 is an enlarged view of a portion (II) of FIG. 1;

FIG. 3A is a cross-sectional view schematically illustrating a method for manufacturing a wiring substrate according to an embodiment of the present invention;

FIG. 3B is a cross-sectional view schematically illustrating a method for manufacturing a wiring substrate according to an embodiment of the present invention;

FIG. 3C is a cross-sectional view schematically illustrating a method for manufacturing a wiring substrate according to an embodiment of the present invention;

FIG. 3D is a cross-sectional view schematically illustrating a method for manufacturing a wiring substrate according to an embodiment of the present invention;

FIG. 3E is a cross-sectional view schematically illustrating a method for manufacturing a wiring substrate according to an embodiment of the present invention;

FIG. 3F is a cross-sectional view schematically illustrating a method for manufacturing a wiring substrate according to an embodiment of the present invention;

FIG. 3G is a cross-sectional view schematically illustrating a method for manufacturing a wiring substrate according to an embodiment of the present invention; and

FIG. 3H is a cross-sectional view schematically illustrating a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

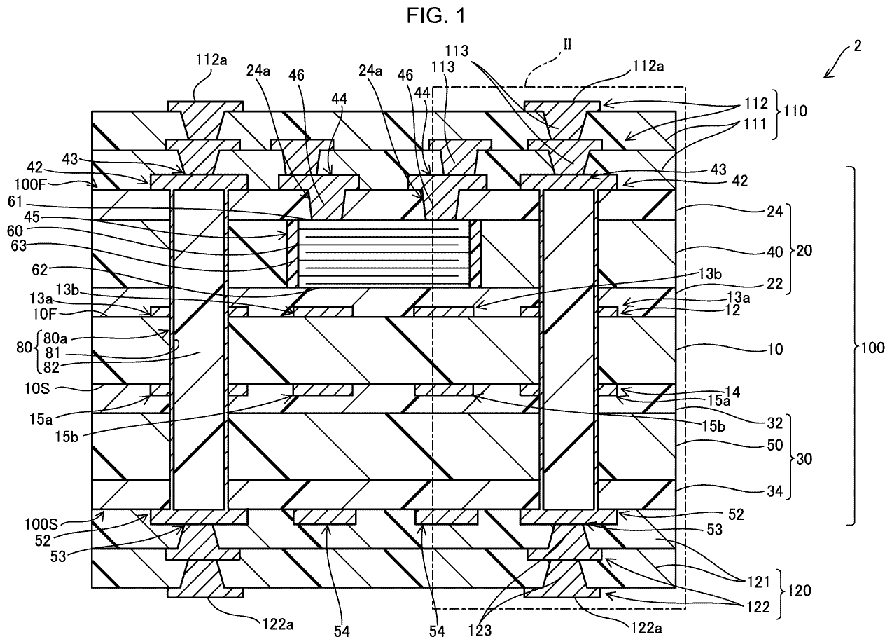

FIG. 1 is a cross-sectional view illustrating a wiring substrate 1 according to an embodiment of the present invention. As illustrated in FIG. 1, the wiring substrate 1 includes a multilayer core substrate 100, a first build-up layer 110, and a second build-up layer 120. The first build-up layer 110 is formed on a first surface (100F) of the multilayer core substrate 100. The second build-up layer 120 is formed on a second surface (100S) of the multilayer core substrate 100.

The multilayer core substrate 100 is formed of a central insulating layer 10, a first-surface-side insulating layer 20, and a second-surface-side insulating layer 30, and has through holes 80, inner-layer conductor layers, surface-layer conductor layers, and connection conductors 46. A component 60 is positioned in the multilayer core substrate 100. The first-surface-side insulating layer 20 is formed on a first surface (10F) of the central insulating layer 10. The second-surface-side insulating layer 30 is formed on a second surface (10S) of the central insulating layer 10. The central insulating layer 10 is sandwiched between the first-surface-side insulating layer 20 and the second-surface-side insulating layer 30. The inner-layer conductor layers are a first inner-layer conductor layer 12 and a second inner-layer conductor layer 14, and the surface-layer conductor layers are a first surface-layer conductor layer 42 and a second surface-layer conductor layer 52.

The first-surface-side insulating layer 20 is formed of a first resin substrate 40, a first insulating layer 22, and a third insulating layer 24. The first insulating layer 22 is formed on the first surface (10F) of the central insulating layer 10. The first resin substrate 40 is formed on a surface of the first insulating layer 22 on a side opposite to the central insulating layer 10. The third insulating layer 24 is formed on a surface of the first resin substrate 40 on a side opposite to the first insulating layer 22. The second-surface-side insulating layer 30 is formed of a second resin substrate 50, a second insulating layer 32, and a fourth insulating layer 34. The second insulating layer 32 is formed on the second surface (10S) of the central insulating layer 10. The second resin substrate 50 is formed on a surface of the second insulating layer 32 on a side opposite to the central insulating layer 10. The fourth insulating layer 34 is formed on a surface of the second resin substrate 50 on a side opposite to the second insulating layer 32. The first-surface-side insulating layer 20 and the second-surface-side insulating layer 30 are each formed of at least two insulating layers. The first-surface-side insulating layer 20 and the second-surface-side insulating layer 30 may each be formed of three or four insulating layers.

In the description of the wiring substrate 1 of the present embodiment, a side farther from the central insulating layer 10 in a thickness direction of the wiring substrate 1 is also referred to as an “upper side” or simply “upper,” and a side closer to the central insulating layer 10 is also referred to as a “lower side” or simply “lower.” Further, for each of the conductor layers and insulating layers, a surface facing away from the central insulating layer 10 is also referred to as an “upper surface,” and a surface facing the central insulating layer 10 is also referred to as a “lower surface.” Therefore, for example, in the description of the first build-up layer 110 and the second build-up layer 120, a side farther from the multilayer core substrate 100 is also referred to as an “upper side,” or simply “upper,” and a side closer to the multilayer core substrate 100 is also referred to as a “lower side,” or simply “lower.” Further, in the description of the wiring substrate 1 of the present embodiment, for each of the conductor layers and insulating layers, the terms “first surface” and “second surface” may be used. In this case, the first surface is described as an upper surface merely for convenience, and it may be either an upper surface or a lower surface.

The first inner-layer conductor layer 12 is formed on the first surface (10F) of the central insulating layer 10. The first inner-layer conductor layer 12 is covered by the first insulating layer 22. The first inner-layer conductor layer 12 may be a single-layer conductor layer or a multilayer conductor layer formed of two or more layers. The first inner-layer conductor layer 12 includes portions that are connected to the through holes 80 and portions that are not directly connected to the through holes 80. The portions of the first inner-layer conductor layer 12 that are connected to the through holes 80 are referred to as first inner-layer through-hole connection parts (13a). The portions of the first inner-layer conductor layer 12 that are not directly connected to the through holes 80 are referred to as first inner-layer through-hole non-connection parts (13b).

The second inner-layer conductor layer 14 is formed on the second surface (10S) of the central insulating layer 10. The second inner-layer conductor layer 14 is covered by the second insulating layer 32. The second inner-layer conductor layer 14 may be a single-layer conductor layer or a multilayer conductor layer formed of two or more layers. The second inner-layer conductor layer 14 includes portions that are connected to the through holes 80 and portions that are not directly connected to the through holes 80. The portions of the second inner-layer conductor layer 14 that are connected to the through holes 80 are referred to as second inner-layer through-hole connection parts (15a). The portions of the second inner-layer conductor layer 14 that are not directly connected to the through holes 80 are referred to as second inner-layer through-hole non-connection parts (15b).

The first surface-layer conductor layer 42 is formed on the outermost layer of the first-surface-side insulating layer 20. Specifically, the first surface-layer conductor layer 42 is formed on the third insulating layer 24, which is the outermost layer of the first-surface-side insulating layer 20. The first surface-layer conductor layer 42 is formed of at least two conductor layers. The first surface-layer conductor layer 42 may be formed of three or four conductor layers. The first surface-layer conductor layer 42 includes portions that are connected to the through holes 80 and portions that are not directly connected to the through holes 80. The portions of the first surface-layer conductor layer 42 that are connected to the through holes 80 are referred to as first surface-layer through-hole connection parts, and first cover conductors 43 are respectively formed in the first surface-layer through-hole connection parts. The portions of the first surface-layer conductor layer 42 that are not directly connected to the through holes 80 are referred to as first surface-layer through-hole non-connection parts 44.

The second surface-layer conductor layer 52 is formed on the outermost layer of the second-surface-side insulating layer 30. Specifically, the second surface-layer conductor layer 52 is formed on the fourth insulating layer 34, which is the outermost layer of the second-surface-side insulating layer 30. The second surface-layer conductor layer 52 is formed of at least two conductor layers. The second surface-layer conductor layer 52 may be formed of three or four conductor layers. The second surface-layer conductor layer 52 includes portions that are connected to the through holes 80 and portions that are not directly connected to the through holes 80. The portions of the second surface-layer conductor layer 52 that are connected to the through holes 80 are referred to as second surface-layer through-hole connection parts, and second cover conductors 53 are respectively formed on the second surface-layer through-hole connection parts. The portion of the second surface-layer conductor layer 52 that are not directly connected to the through holes 80 are referred to as second surface-layer through-hole non-connection parts 54.

The through holes 80 are formed between the first surface-layer conductor layer 42 and the second surface-layer conductor layer 52. The through holes 80 are connected to the first surface-layer conductor layer 42 and the second surface-layer conductor layer 52, and are also connected to the first inner-layer conductor layer 12 and the second inner-layer conductor layer 14. That is, the through holes 80 are connected to four conductor layers.

The through hole 80 is formed of an inner-wall conductor layer 81 and a filler 82. The inner-wall conductor layer 81 is a conductor layer formed on an inner wall of a through-hole opening (80a). The inner-wall conductor layer 81 may be a single-layer conductor layer or a conductor layer formed of two or more layers. A surface of the inner-wall conductor layer 81 may be subjected to a surface treatment such as roughening. The filler 82 is formed in the through-hole openings (80a). The through-hole openings (80a) of the through holes 80 penetrate the central insulating layer 10, the first-surface-side insulating layer 20, and the second-surface-side insulating layer 30.

In the outermost layer on the first-surface-side insulating layer 20 side of the through holes 80, the inner-wall conductor layer 81 and the first cover conductors 43, which are the first surface-layer through-hole connection parts of the first surface-layer conductor layer 42, are formed. The first cover conductors 43 each cover an end surface of the filler 82. The first cover conductors 43 are each a part of the first surface-layer conductor layer 42. The first surface-layer through-hole connection parts may be in a form where the end surface of the filler 82 is exposed without being covered. In the outermost layer on the second-surface-side insulating layer 30 side of the through holes 80, the inner-wall conductor layer 81 and the second cover conductors 53, which are the second surface-layer through-hole connection parts of the second surface-layer conductor layer 53, are formed. The second cover conductors 53 each cover an end surface of the filler 82. The second cover conductors 53 are each a part of the second surface-layer conductor layer 53. The second surface-layer through-hole connection parts may be in a form where the end surface of the filler 82 is exposed without being covered.

The through holes 80 are connected to the first inner-layer conductor layer 12 and the second inner-layer conductor layer 14. In the first inner-layer through-hole connection parts (13a) of the first inner-layer conductor layer 12 that are connected to the through holes 80, openings for forming the through holes 80 are provided. In the second inner-layer through-hole connection parts (15a) of the second inner-layer conductor layer 14 that are connected to the through holes 80, openings for forming the through holes 80 are provided.

Although a thickness (T1) of each of the inner-layer conductor layers and a thickness (T2) of each of the surface-layer conductor layers are not particularly limited, it is desirable that the thickness (T1) of each of the inner-layer conductor layers and the thickness (T2) of each of the surface-layer conductor layers satisfy a relationship of Formula (1): T1<T2.

When the thickness (T1) of each of the inner-layer conductor layers and the thickness (T2) of each of the surface-layer conductor layers satisfy the relationship of Formula (1), formation of the through holes 80 becomes stable. When the multilayer core substrate 100 is formed, warpage of the substrate is reduced, and the formation of the build-up layers (110, 120) also becomes stable. Therefore, it is thought that when it is used to form the wiring substrate, warpage is suppressed and connection between the conductor layers is stable.

Although the number of layers (S1) of the inner-layer conductor layers and the number of layers (S2) of the surface-layer conductor layers are not particularly limited, it is desirable that the number of layers (S1) of the inner-layer conductor layers and the number of layers (S2) of the surface-layer conductor layers satisfy a relationship of Formula (2): S1<S2.

When the number of layers (S1) of the inner-layer conductor layers and the number of layers (S2) of the surface-layer conductor layers satisfy the relationship of Formula (2), formation of the through holes 80 becomes stable. When the multilayer core substrate 100 is formed, warpage of the substrate is reduced, and the formation of the build-up layers (110, 120) also becomes stable. Therefore, it is thought that when it is used to form the wiring substrate, warpage is suppressed and connection between the conductor layers is stable.

Further, it is even more desirable that the thickness (T1) of each of the inner-layer conductor layers and the thickness (T2) of each of the surface-layer conductor layers satisfy the relationship of Formula (1), and the number of layers (S1) of the inner-layer conductor layers and the number of layers (S2) of the surface-layer conductor layers satisfy the relationship of Formula (2). When the two relational expressions are satisfied, the formation of the through holes 80 is stable. When the multilayer core substrate 100 is formed, warpage of the substrate is reduced, and the formation of the build-up layers (110, 120) also becomes stable. Therefore, it is thought that when it is used to form the wiring substrate, warpage is suppressed and connection between the conductor layers is stable. It is thought that even when a reliability test is performed, defects such as insulation failure are unlikely to occur at an early stage.

The component 60 is positioned in the first-surface-side insulating layer 20. An opening 45 penetrating the first resin substrate 40 is formed in the first resin substrate 40. The component 60 is accommodated in the opening 45. The component 60 is an electronic component. Specifically, the electronic component is a capacitor, an inductor, an IVR, a semiconductor, or the like. The component 60 has an electrode surface 61 and a non-electrode surface 62 on a side opposite to the electrode surface 61. The non-electrode surface 62 of the component 60 faces the first insulating layer 22. The electrode surface 61 of the component 60 faces the third insulating layer 24. The connection conductors 46 penetrating the third insulating layer 24 are formed in the third insulating layer 24, and the connection conductors 46 are connected to the first surface-layer through-hole non-connection parts 44, which are portions of the first surface-layer conductor layer 42 that are not directly connected to the through holes 80. The electrode surface 61 is connected to the connection conductors 46. As a result, the electrode surface 61 of the component 60 is connected to the first surface-layer through-hole non-connection parts 44 via the connection conductors 46. Thus, the component 60 and the first surface-layer conductor layer 42 are connected to each other. A gap between an inner surface of the opening 45 and the component 60 is filled with an embedding resin 63. The embedding resin 63 is, for example, a thermosetting resin. The embedding resin 63 may also be a photocurable resin. The embedding resin 63 is provided separately from the first insulating layer 22, the first resin substrate 40, and the third insulating layer 24. Multiple components 60 may be accommodated in the opening 45, and identical components or different components may be positioned.

The first build-up layer 110 and the second build-up layer 120 are formed on the multilayer core substrate 100. The first build-up layer 110 is formed on the first surface (100F) of the multilayer core substrate 100 and includes one or more build-up layers including an insulating layer 111, a conductor layer 112, and via conductors 113. The second build-up layer 120 is formed on the second surface (100S) of the multilayer core substrate 100 and includes one or more build-up layers including an insulating layer 121, a conductor layer 122, and via conductors 123.

In the example illustrated in FIG. 1, the first build-up layer 110 includes two insulating layers 111 and two conductor layers 112, and the second build-up layer 120 includes two insulating layers 121 and two conductor layers 122. Each insulating layer 111 includes via conductors 113 that connect the conductor layer on the insulating layer 111 to the conductor layer below the insulating layer 111. Each insulating layer 121 includes via conductors 123 that connect the conductor layer on the insulating layer 121 to the conductor layer below the insulating layer 121. It is also possible that a build-up layer is formed only on one side of the multilayer core substrate. In this case, only the first build-up layer 110 or only the second build-up layer 120 is formed on the multilayer core substrate.

In the illustrated example, the first build-up layer 110 and the second build-up layer 120 each include two conductor layers and two insulating layers. However, it is also possible that the first build-up layer 110 and the second build-up layer 120 each include three or more conductor layers and three or more insulating layers, or each include only one conductor layer and one insulating layer.

Connection pads (112a) are formed in the conductor layer 112 that is on the surface side in the first build-up layer 110 and is positioned as an outermost layer of the wiring substrate 1, and connection pads (122a) are formed in the conductor layer 122 that is on the surface side in the second build-up layer 120 and is positioned as an outermost layer of the wiring substrate 1. An external electronic component, a motherboard (not illustrated), or the like is mounted on the connection pads (112a). When an electronic component is mounted, bumps (not illustrated) formed of any metal such as solder, copper, or tin are formed on the connection pads (112a) or the connection pads (122a).

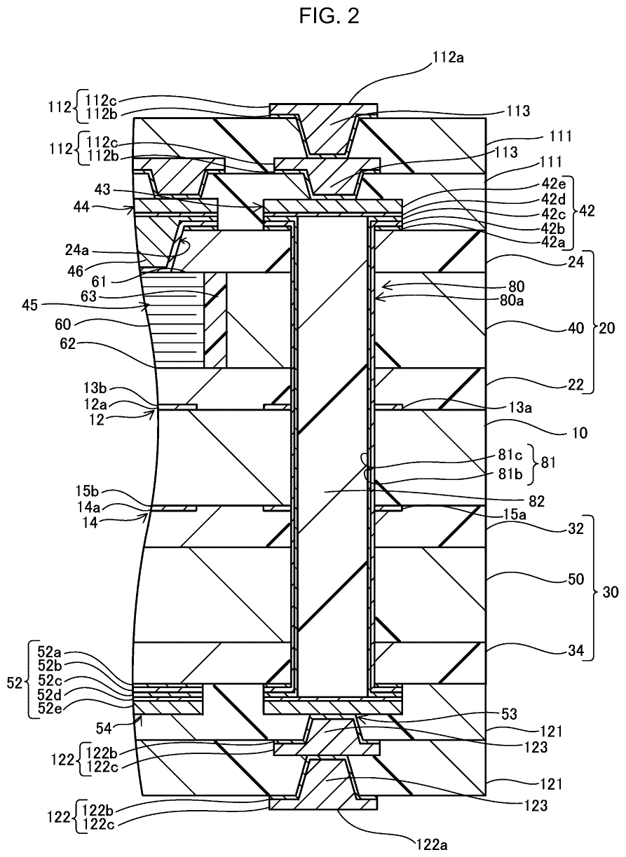

In the wiring substrate 1, any conductor patterns are formed in the first inner-layer conductor layer 12, the second inner-layer conductor layer 14, the first surface-layer conductor layer 42, the second surface-layer conductor layer 52, the conductor layers 112 in the first build-up layer 110, and the conductor layers 122 in the second build-up layer 120. These conductor layers are simplified for clarity and are illustrated as each having a single-layer structure. However, as will be described in detail below with reference to FIG. 2, these conductor layers may each have a multilayer structure including 2 or more layers.

The insulating layers and resin substrates that constitute the multilayer core substrate 100 are not particularly limited, but are desirably each obtained by impregnating a core material serving as a reinforcing material with an insulating resin and curing the same. As the insulating resin, an epoxy resin, a bismaleimide triazine resin (BT resin), a phenol resin, or the like can be used. Examples of the reinforcing material include glass fiber, aramid fiber, glass nonwoven fabric, aramid nonwoven fabric, and the like. By including a core material in the insulating layers and resin substrates, a wiring substrate 1 is provided that has high rigidity and in which occurrence of warpage is suppressed. On the other hand, the insulating layers 111 and insulating layers 121 used as build-up layers are preferably formed of an insulating resin that does not contain a core material. This is because an insulating resin that does not contain a core material is suitable for via formation. Further, the insulating layers may each contain an inorganic filler such as silica.

With reference to FIG. 2, structures of the conductors included in the wiring substrate 1 are described in detail. FIG. 2 illustrates an enlarged view of a portion (II) of FIG. 1.

As illustrated in FIG. 2, the first inner-layer conductor layer 12 is formed by a metal foil layer (12a) formed on the first surface (10F) of the central insulating layer 10. The second inner-layer conductor layer 14 is formed by a metal foil layer (14a) formed on the second surface (10S) of the central insulating layer 10. The metal foil layer (12a) of the first inner-layer conductor layer 12 and the metal foil layer (14a) of the second inner-layer conductor layer 14 each have a single-layer structure, but may have a multilayer structure including two or more layers. The type of metal foil used for the metal foil layer (12a) and metal foil layer (14a) is not particularly limited, but it is preferable to use one containing copper as a main component in view of conductivity.

Each conductor layer according to an embodiment of the present invention is formed of any combination of a metal foil layer, a seed layer, and an electrolytic plating layer. The metal foil layer is a conductor layer formed by patterning a metal foil formed on an insulating layer. The type of metal used for the metal foil is not particularly limited, but it is preferable to use one containing copper as a main component in view of conductivity. The seed layer is a conductor layer formed by forming a seed film such as an electroless plating film or a sputtered film on an entire surface of a substrate and patterning the same. The type of metal in the seed film is not particularly limited, but it is preferable to use one containing copper, nickel, or titanium as a main component. The electrolytic plating layer is a conductor layer formed by patterning a resist on a seed film formed on a substrate and depositing an electrolytic plating film in regions where the resist is not formed. The type of metal in the electrolytic plating film is not particularly limited, but it is preferable to use one containing copper as a main component in view of conductivity.

The first surface-layer conductor layer 42 is formed of a metal foil layer, a seed layer, and an electrolytic plating layer. Specifically, the first surface-layer conductor layer 42 is formed of a metal foil layer (42a) formed on the upper surface of the third insulating layer 24, a seed layer (42b) formed on the metal foil layer (42a), an electrolytic plating layer (42c) formed on the seed layer (42b), a seed layer (42d) formed on the electrolytic plating layer (42c), and an electrolytic plating layer (42e) formed on the seed layer (42d). The first surface-layer conductor layer 42 has a five-layer structure including the metal foil (42a), the seed layer (42b), the electrolytic plating layer (42c), the seed layer (42d), and the electrolytic plating layer (42e). Further, the first cover conductors 43 are formed of the seed layer (42d) and the electrolytic plating layer (42e). That is, the first surface-layer conductor layer 42 has a five-layer structure.

The connection conductors 46 are formed in holes (24a) that penetrate the third insulating layer 24 and expose the electrode surface 61 of the component 60. The connection conductors 46 are formed of a seed layer (42b) formed on inner wall surfaces of the holes (24a) and on the electrode surface 61, and an electrolytic plating layer (42c) formed on the seed layer (42b) and filling the holes (24a). The seed layer (42b) and electrolytic plating layer (42c) that form the connection conductors 46 are common to the seed layer (42b) and electrolytic plating layer (42c) that form the first surface-layer conductor layer 42. The first surface-layer conductor layer 42 and the connection conductors 46 are formed at the same time. The connection conductors 46 connect the electrode surface 61 of the component 60 and the first surface-layer through-hole non-connection parts 44.

The second surface-layer conductor layer 52 is formed of a metal foil layer, a seed layer, and an electrolytic plating layer. Specifically, the second surface-layer conductor layer 52 is formed of a metal foil layer (52a) formed on the upper surface of the fourth insulating layer 34, a seed layer (52b) formed on the metal foil layer (52a), an electrolytic plating layer (52c) formed on the seed layer (52b), a seed layer (52d) formed on the electrolytic plating layer (52c), and an electrolytic plating layer (52e) formed on the seed layer (52d). The second surface-layer conductor layer 52 has a five-layer structure including the metal foil layer (52a), the seed layer (52b), the electrolytic plating layer (52c), the seed layer (52d), and the electrolytic plating layer (52e). Further, the second cover conductors 53 are formed of the seed layer (52d) and the electrolytic plating layer (52e). That is, the second surface-layer conductor layer 52 has a five-layer structure.

In the wiring substrate 1 of the embodiment, it is desirable that the thickness (T1) of each of the inner-layer conductor layers (the first inner-layer conductor layer 12 and the second inner-layer conductor layer 14) and the thickness (T2) of each of the surface-layer conductor layers (the first surface-layer conductor layer 42 and the second surface-layer conductor layer 52) satisfy the following relationship (Formula 1):

T1<T2 (Formula 1)

When the thickness (T1) of each of the inner-layer conductor layers and the thickness (T2) of each of the surface-layer conductor layers satisfy the relationship of Formula (1), formation of the through holes 80 becomes stable. When the multilayer core substrate 100 is formed, warpage of the substrate is reduced, and the formation of the build-up layers (110, 120) also becomes stable. Therefore, it is thought that when it is used to form the wiring substrate, warpage is suppressed and connection between the conductor layers is stable. Specifically, the thickness (T1) of each of the inner-layer conductor layers refers to a thickness of each of the first inner-layer through-hole connection parts (13a) and second inner-layer through-hole connection parts (15a), and the thickness (T2) of each of the surface-layer conductor layers refers to a thickness of each of the first surface-layer through-hole connection parts and second surface-layer through-hole connection parts.

Further, it is desirable that the number of layers (S1) of the inner-layer conductor layers (the first inner-layer conductor layer 12 and the second inner-layer conductor layer 14) and the number of layers (S2) of the surface-layer conductor layers (the first surface-layer conductor layer 42 and the second surface-layer conductor layer 52) satisfy the following relationship of Formula 2: S1<S2.

When the number of layers (S1) of the inner-layer conductor layers and the number of layers (S2) of the surface-layer conductor layers satisfy the relationship of Formula (2), formation of the through holes 80 becomes stable. When the multilayer core substrate 100 is formed, warpage of the substrate is reduced, and the formation of the build-up layers (110, 120) also becomes stable. Therefore, it is thought that when it is used to form the wiring substrate, warpage is suppressed and connection between the conductor layers is stable. Specifically, the number of layers (S1) of the inner-layer conductor layers refers to the number of layers of the first inner-layer through-hole connection parts (13a) and the second inner-layer through-hole connection parts (15a), and the number of layers (S2) of the surface-layer conductor layers refers to the number of layers of the first surface-layer through-hole connection parts and the second surface-layer through-hole connection parts.

Further, it is even more desirable that the thickness (T1) of each of the inner-layer conductor layers and the thickness (T2) of each of the surface-layer conductor layers satisfy the relationship of Formula (1), and the number of layers (S1) of the inner-layer conductor layers and the number of layers (S2) of the surface-layer conductor layers satisfy the relationship of Formula (2). When the two relational expressions are satisfied, the formation of the through holes 80 is stable. When the multilayer core substrate 100 is formed, warpage of the substrate is reduced, and the formation of the build-up layers (110, 120) also becomes stable. Therefore, it is thought that when it is used to form the wiring substrate, warpage is suppressed and connection between the conductor layers is stable. It is thought that even when a reliability test is performed, defects such as insulation failure are unlikely to occur at an early stage.

The through holes 80 are formed of the inner-wall conductor layer 81 and the filler 82. The inner-wall conductor layer 81 of the through holes 80 is formed of a seed layer (81b) formed on the inner wall surfaces of the through-hole openings (80a) and an electrolytic plating layer (81c) formed on the seed layer (81b). The seed layer (81b) is common to the seed layers (42b, 52b) and is formed at the same time as the seed layers (42b, 52b). The electrolytic plating layer (81c) is common to the electrolytic plating layers (42c, 52c) and is formed at the same time as the electrolytic plating layers (42c, 52c). The through holes 80 are filled with the filler 82. The filler 82 is formed using an insulating material containing, for example, a resin such as epoxy resin, acrylic resin, or phenolic resin. Alternatively, the filler 82 may be a solidified conductive paste or conductive ink containing metal particles such as silver or copper. By forming the filler 82 in the through holes 80, it becomes possible to form via conductors directly on the through holes 80. The first and second cover conductors (43, 53) are formed on the end surfaces of the filler 82 so as to cover the end surfaces of the filler 82. A conductive material may be used for the filler 82.

The conductor layers 112 of the first build-up layer 110 are each formed of a seed layer (112b) and an electrolytic plating layer (112c), and each include two conductor layers. The conductor layers 122 of the second build-up layer 120 are each formed of a seed layer (122b) and an electrolytic plating layer (122c), and each include two conductor layers.

The via conductors 113 in the first build-up layer 110 are each formed of a seed layer (112b) and an electrolytic plating layer (112c), and each include two conductor layers. The seed layer (112b) and electrolytic plating layer (112c) of the via conductors 113 are common to the seed layer (112b) and electrolytic plating layer (112c) of the conductor layers 112. The via conductors 123 in the second build-up layer 120 are each formed of a seed layer (122b) and an electrolytic plating layer (122c), and each include two conductor layers. The seed layer (122b) and electrolytic plating layer (122c) of the via conductors 123 are common to the seed layer (122b) and electrolytic plating layer (122c) of the conductor layers 122.

### Method for Manufacturing Wiring Substrate

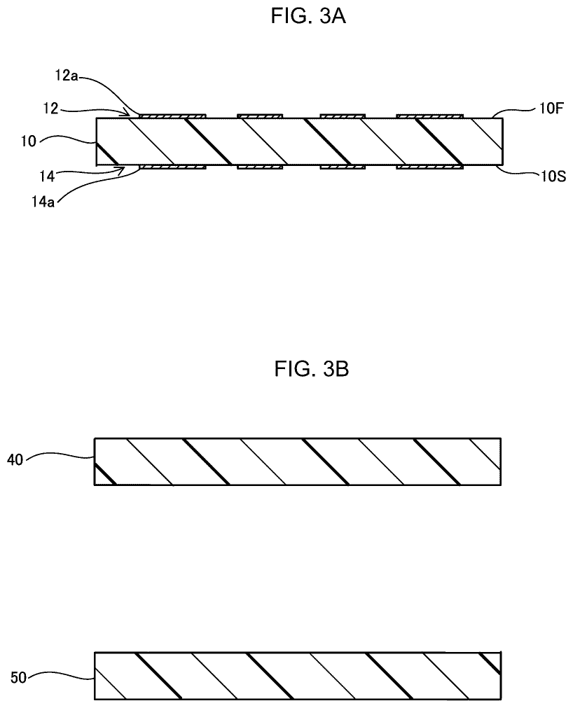

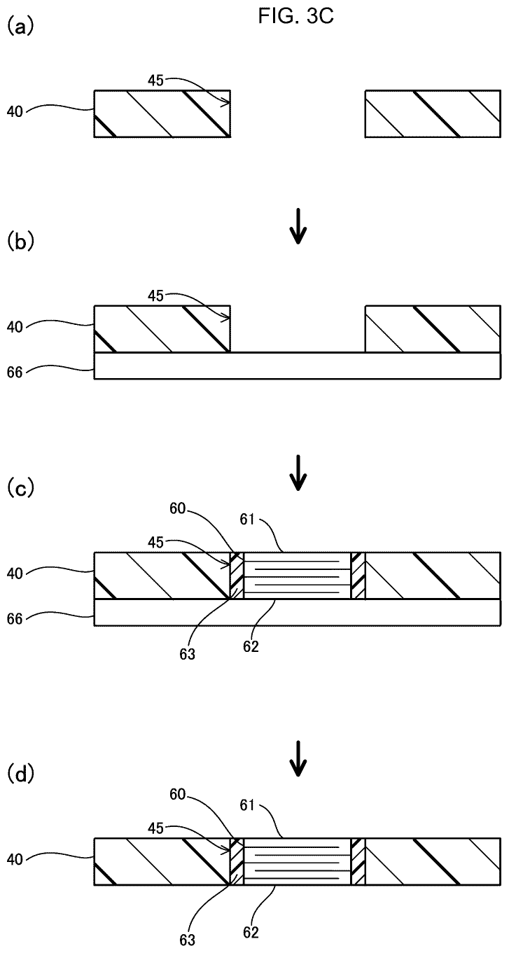

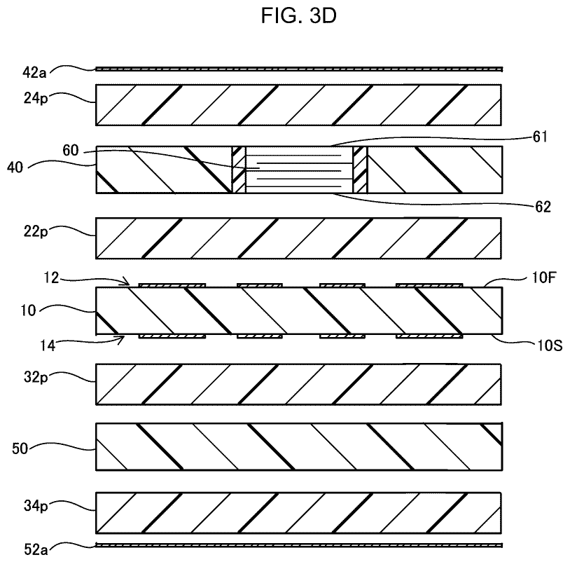

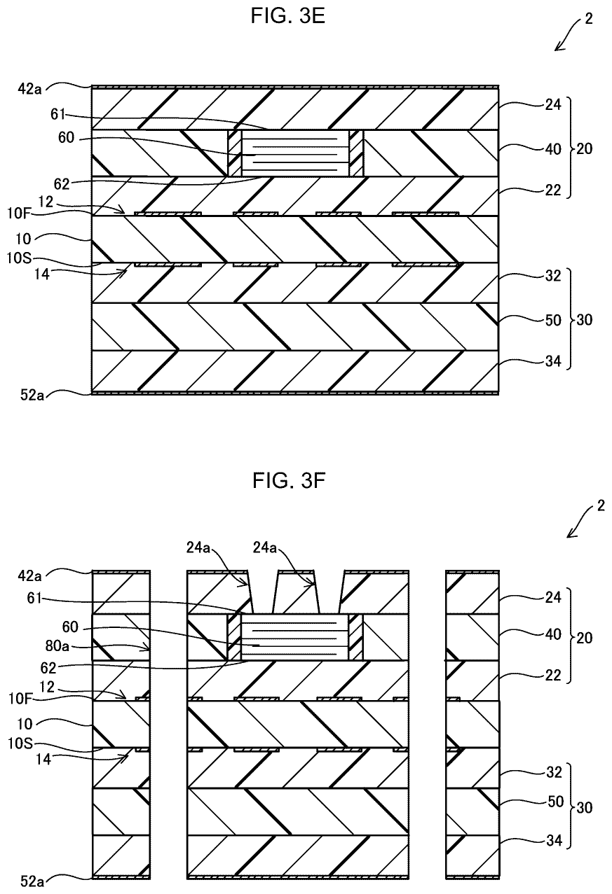

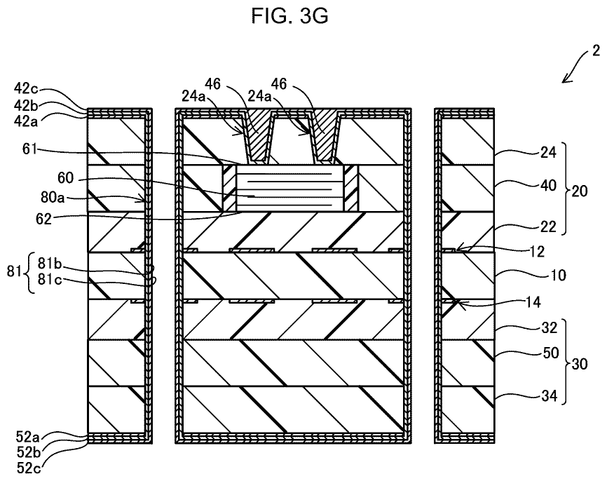

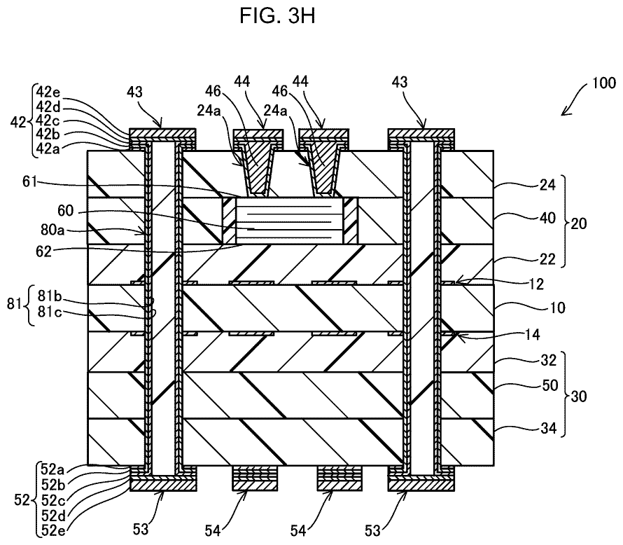

FIGS. 3A-3H illustrate a method for manufacturing the wiring substrate 1 of the embodiment. FIGS. 3A-3H are cross-sectional views. As illustrated in FIG. 3A, the central insulating layer 10 is prepared in which the first inner-layer conductor layer 12 is formed on the first surface (10F) and the second inner-layer conductor layer 14 is formed on the second surface (10S). For the central insulating layer 10, a double-sided copper-clad laminate in which metal foils are formed on both surfaces of a resin substrate containing a core material is used as a starting material, and the first inner-layer conductor layer 12 and second inner-layer conductor layer 14 having desired conductor patterns are formed from the metal foils using a subtractive method involving processes such as etching using a mask on which wirings are drawn. As a result, the central insulating layer 10 having the conductor layers formed on both surfaces is obtained. For the central insulating layer 10, desired conductor patterns may be formed based on metal formed on both surfaces of an insulating material by sputtering, plating, or the like.

As illustrated in FIG. 3B, the first resin substrate 40, on both surfaces of which no metal foil is formed, is prepared. The first resin substrate 40 is prepared using a double-sided copper-clad laminate in which metal foils are formed on both surfaces of a resin substrate containing a core material as a starting material. As an example, the first resin substrate 40 is formed by removing the metal foils on both surfaces of the double-sided copper-clad laminate by etching the entire surfaces. Similarly, the second resin substrate 50, on both surfaces of which no metal foil is formed, is also prepared. Alternatively, a resin substrate without metal foil may be used.

As illustrated in (a) of FIG. 3C, the opening 45 is formed in the first resin substrate 40. The opening 45 penetrates between the upper surface and the lower surface of the first resin substrate 40. The opening 45 is formed using laser, router, or the like.

As illustrated in (b) of FIG. 3C, the first resin substrate 40 in which the opening 45 is formed is placed on a support plate 66. The lower surface of the first resin substrate 40 faces the support plate 66. A lower surface side of the opening 45 in the first resin substrate 40 is closed by the support plate 66. The lower surface of the first resin substrate 40 and the support plate 66 may be bonded to each other via a release agent.

As illustrated in (c) of FIG. 3C, the component 60 is positioned in the opening 45. The non-electrode surface 62 of the component 60 is positioned on the support plate 66 exposed through the opening 45. In this case, by providing an adhesive layer between the non-electrode surface 62 of the component 60 and the support plate 66, the component 60 is fixed on the support plate 66. The electrode surface 61 of the component 60 is flush with the upper surface of the first resin substrate 40. It is also possible that the electrode surface 61 of the component 60 is lower than the upper surface of the first resin substrate 40. The embedding resin 63 is filled in the gap between the opening 45 of the first resin substrate 40 and the component 60. The filling of the embedding resin 63 is performed, for example, by potting. The embedding resin 63 is preferably a thermosetting resin or a photocurable resin. The embedding resin 63 is cured. The component 60 is fixed in the opening 45.

As illustrated in (d) of FIG. 3C, after the embedding resin 63 is cured, the support plate 66 is removed. The first resin substrate 40 in which the component 60 is accommodated is formed.

As illustrated in FIG. 3D, a metal foil (42a), a prepreg (24p) to be cured to form the third insulating layer 24, the first resin substrate 40 in which the component 60 is accommodated, a prepreg (22p) to be cured to form the first insulating layer 22, the central insulating layer 10, a prepreg (32p) to be cured to form the second insulating layer 32, the second resin substrate 50, a prepreg (34p) to be cured to form the fourth insulating layer 34, and a metal foil (52a) are prepared. The prepreg (22p) is positioned on the first surface (10F) side of the central insulating layer 10, the first resin substrate 40 is positioned on the prepreg (22p), the prepreg (24p) is positioned on the first resin substrate 40, and the metal foil (42a) is positioned on the prepreg (24p). The prepreg (32p) is positioned on the second surface (10S) side of the central insulating layer 10, the second resin substrate 50 is positioned on the prepreg (32p), the prepreg (34p) is positioned on the second resin substrate 50, and the metal foil (52a) is positioned on the prepreg (34p).

As illustrated in FIG. 3E, the metal foil (42a), the prepreg (24p), the first resin substrate 40, the prepreg (22p), the central insulating layer 10, the prepreg (32p), the second resin substrate 50, the prepreg (34p), and the metal foil (52a) in the positions illustrated in FIG. 3D are stacked and then collectively pressed. Thermal curing may be performed simultaneously with the collective pressing, or after the pressing. After the collective pressing, the prepregs (22p, 32p, 24p, 34p) are cured to become the first insulating layer 22, the second insulating layer 32, the third insulating layer 24, and the fourth insulating layer 34. The first-surface-side insulating layer 20 including the first insulating layer 22, the first resin substrate 40, and the third insulating layer 24 is formed on the first surface (10F) of the central insulating layer 10. The second-surface-side insulating layer 30 including the second insulating layer 32, the second resin substrate 50, and the fourth insulating layer 34 is formed on the second surface (10S) of the central insulating layer 10. The metal foil (42a) is formed on the third insulating layer 24, and the metal foil (52a) is formed on the fourth insulating layer 34. After the pressing, the first inner-layer conductor layer 12 is embedded in the first insulating layer 22. After the pressing, the second inner-layer conductor layer 14 is embedded in the second insulating layer 32. An intermediate substrate 2 including the first-surface-side insulating layer 20, the central insulating layer 10, and the second-surface-side insulating layer 30 is formed.

In this case, for convenience of description, the first-surface-side insulating layer 20 and the second-surface-side insulating layer 30 are described as having the same thickness. However, the first-surface-side insulating layer 20 and the second-surface-side insulating layer 30 may differ in thickness. Specifically, the thickness of the first-surface-side insulating layer 20 may be made smaller than the thickness of the second-surface-side insulating layer 30. As a result, an overall thickness of the multilayer core substrate can be adjusted. When a component is positioned in a resin substrate, the thickness can also be adjusted according to the thickness of the component.

As illustrated in FIG. 3F, through-hole openings are formed in the intermediate substrate 2. The through-hole openings (80a) that penetrate the metal foil (42a), the third insulating layer 24, the first resin substrate 40, the first insulating layer 22, the first inner-layer conductor layer 12, the central insulating layer 10, the second inner-layer conductor layer 14, the second insulating layer 32, the second resin substrate 50, the fourth insulating layer 34, and the metal foil (52a) of the intermediate substrate 2 are formed. The through-hole openings (80a) are formed, for example, by drilling using a cutting device such as a drill. The through-hole openings (80a) may also be formed by laser irradiation. Further, the holes (24a) that penetrate the metal foil (42a) and the third insulating layer 24 and expose the electrode surface 61 of the component 60 are formed. The holes (24a) are formed, for example, by laser irradiation.

As illustrated in FIG. 3G, conductors are formed in the through-hole openings (80a) of the intermediate substrate 2. A seed film is formed on the metal foil of the intermediate substrate 2 and on inner walls of the through-hole openings. Specifically, a seed film (42b) is formed on the metal foil (42a) of the intermediate substrate 2, and a seed film (81b) is formed on the inner walls of the through-hole openings (80a). A seed film (52b) is formed on the metal foil (52a). The seed films (42b, 81b, 52b) are formed at the same time, and the metal films are formed by, for example, electroless plating or sputtering. An electrolytic plating film is formed using the metal layer serving as a seed film as a power feeding layer. Electrolytic plating films (42c, 81c, 52c) are formed on the seed films. The inner-wall conductor layer 81 formed of the seed film (81b) and the electrolytic plating film (81c) is formed on the inner walls of the through-hole openings. The electrolytic plating film (42c) fills the holes (24a). The connection conductors 46 are formed of the seed layer (42b) formed on the inner walls of the holes (24a) and the electrolytic plating layer (42c) filling the holes (24a).

The filler 82 is filled in cavities of the through-hole openings (80a). For example, a resin such as epoxy resin, acrylic resin, or phenolic resin is injected into each through-hole opening (80a) from one or both ends. The through-hole openings (80a) may be filled with, for example, a conductive paste containing conductive particles such as silver particles, instead of an insulating resin such as epoxy resin, as the filler 82. The insulating resin such as epoxy resin or the conductive paste used for the filler 82 is solidified when necessary by heating or the like to form the filler 82. The through holes 80 are formed of the inner-wall conductor layer 81 and the filler 82 in the through-hole openings (80a). End surfaces of the filler 82 after solidification may be polished using any suitable method, such as chemical polishing or mechanical polishing, when necessary. By the polishing, each of both end surfaces of the filler 82 and surfaces of the electrolytic plating films (42c, 52c) are preferably made substantially flush with each other.

Further, on the electrolytic plating film (42c) and the filler 82 on the first-surface side of the intermediate substrate 2, a seed film (42d) and an electrolytic plating film (42e) are sequentially formed. At the same time, on the electrolytic plating film (52c) and the filler 82 on the second-surface side of the intermediate substrate 2, a seed film (52d) and an electrolytic plating film (52e) are sequentially formed. The seed films (42d, 52d) and the electrolytic plating films (42e, 52e) are formed, for example, using the same methods as the seed layers (42b, 52b) and the electrolytic plating layers (42c, 52c). On the third insulating layer 24, a five-layer structure including the metal foil film (42a), the seed film (42b), the electrolytic plating film (42c), the seed film (42d), and the electrolytic plating film (42e) is formed. On the fourth insulating layer 34, a five-layer structure including the metal foil film (52a), the seed film (52b), the electrolytic plating film (52c), the seed film (52d), and the electrolytic plating film (52e) is formed. After that, as illustrated in FIG. 3H, the first surface-layer conductor layer 42 and second surface-layer conductor layer 52 having desired conductor patterns are formed using a subtractive method involving processes such as etching using a mask on which wirings are drawn. At the same time, on the ends of the filler 82 on the first-surface-side insulating layer 20 side (third insulating layer 24 side), the first cover conductors 43 composed of the seed film (42d) and the electrolytic plating film (42e) are formed. The first cover conductors 43 have a five-layer structure including the metal foil layer (42a), the seed layer (42b), the electrolytic plating layer (42c), the seed layer (42d), and the electrolytic plating layer (42e). On the ends of the filler 82 on the second-surface-side insulating layer 30 side (fourth insulating layer 34 side), the second cover conductors 53 composed of the seed film (52d) and the electrolytic plating film (52e) are formed. The second cover conductors 53 have a five-layer structure including the metal foil layer (52a), the seed layer (52b), the electrolytic plating layer (52c), the seed layer (52d), and the electrolytic plating layer (52e). The multilayer core substrate 100 is formed including the central insulating layer 10, the first-surface-side insulating layer 20, the second-surface-side insulating layer 30, the through holes 80, the first inner-layer conductor layer 12, the second inner-layer conductor layer 14, the first surface-layer conductor layer 42, and the second surface-layer conductor layer 52. As an example of the multilayer core substrate 100, the thickness (T1) of the first inner-layer conductor layer 12 and the second inner-layer conductor layer 14 is 10 μm, and the number of layers (S1) of the first inner-layer conductor layer 12 and the second inner-layer conductor layer 14 is 1 (single layer). The thickness (T2) of the first surface-layer conductor layer 42 and the second surface-layer conductor layer 52 is 25 μm, and the number of layers (S2) of the first surface-layer conductor layer 42 and the second surface-layer conductor layer 52 is 5 (five layers).

The build-up layers are formed on both surfaces of the multilayer core substrate 100. The first build-up layer 110 is formed on the first surface (100F) of the multilayer core substrate 100. The second build-up layer 120 is formed on the second surface (100S) of the multilayer core substrate 100. For example, a film-like insulating resin (for example, epoxy resin) without a reinforcing material is thermocompression bonded to the first surface (100F) and the second surface (100S), thereby forming the insulating layer 111 on the first surface (100F) side among the two insulating layers 111 and the insulating layer 121 on the second surface (100S) side among the two insulating layers 121. The through-hole openings are formed, for example, using CO₂ laser at locations where the via conductors 113 or the via conductors 123 are to be formed in the insulating layer 111 or the insulating layer 121. A seed film made of a conductor, such as copper, is formed on inner walls of the through-hole openings and on surfaces of the insulating layers (111, 121) by electroless plating or sputtering or the like. A plating resist having openings for forming a conductor layer is formed, and an electrolytic plating film is formed in the openings by electrolytic plating using the seed film as a power feeding layer. Through resist stripping and etching, a conductor layer 112 and a conductor layer 122, as well as via conductors 113 and via conductors 123, each including a seed layer and an electrolytic plating layer, are formed. That is, the conductor layer 112 on the first surface (100F) side among the two conductor layers 112 and the conductor layer 122 on the second surface (100S) side among the two conductor layers 122 are formed using a semi-additive method (SAP) without using a metal foil. Along with the conductor layers (112, 122), the via conductors 113 penetrating the insulating layer 111 on the first surface (100F) side and the via conductors 123 penetrating the insulating layer 121 on the second surface (100S) side are formed.

Further, the insulating layer 111 and insulating layer 121 on the surface-layer sides are formed in the same manner as the insulating layer 111 on the first surface (100F) side and the insulating layer 121 on the second surface (100S) side. Further, the conductor layers (112, 122) on the surface-layer sides are formed in the same manner as the conductor layer 112 on the first surface (100F) side and the conductor layer 122 on the second surface (100S) side. Further, the via conductors (113, 123) penetrating the respective insulating layers (111, 121) on the surface-layer sides are formed in the same manner as the via conductor 113 penetrating the insulating layer 111 on the first surface (100F) side and the via conductor 123 penetrating the insulating layer 121 on the second surface (100S) side. In this way, the first build-up layer 110 and the second build-up layer 120 are formed. The wiring substrate 1 of the embodiment (FIG. 1) is obtained.

In the wiring substrate 1 of the embodiment, the through holes 80 are connected to the first surface-layer conductor layer 42, the second surface-layer conductor layer 52, the first inner-layer conductor layer 12, and the second inner-layer conductor layer 14. The through holes 80 are connected to four conductor layers. Therefore, the number of the conductor layers connected to the through holes is reduced, and thus, delay in signal transmission in the through holes 80 is suppressed. Further, since signal delay is suppressed, parasitic capacitance of the through holes 80 is reduced. Specifically, compared to the number of the conductor layers of the through holes in the multilayer core substrate described in International Publication No. 2001/19148, the wiring substrate 1 of the embodiment has a reduced number of conductor layers connected to the through holes.

In a wiring substrate according to an embodiment of the present invention, the through holes are connected to the first surface-layer conductor layer, the second surface-layer conductor layer, the first inner-layer conductor layer, and the second inner-layer conductor layer. The through holes are connected to four conductor layers. Therefore, the number of the conductor layers connected to the through holes is reduced, and thus, delay in signal transmission in the through holes is suppressed. Further, since signal delay is suppressed, parasitic capacitance of the through holes is reduced.

International Publication No. 2001/19148 describes a wiring board that includes a multilayer core substrate with through holes formed therein and build-up wiring layers formed on both surfaces of the multilayer core substrate. The multilayer core substrate includes resin substrates and adhesive resin layers, and has a multilayer insulating layer structure (seven layers in total) including a first resin substrate, a second resin substrate laminated on the first resin substrate via an adhesive resin layer, and a third resin substrate laminated on the second resin substrate via an adhesive resin layer. On both surfaces of each resin substrate, conductor circuits composed of conductor layers are formed. The through holes are connected to the conductor circuits formed on both surfaces of each resin substrate and include a total of six conductor layers.

With demand for higher signal speed and larger capacity, an issue of signal transmission delay in the through holes has arisen. In the wiring board of International Publication No. 2001/19148, it is thought that the signal delay is caused by the number of layers of the conductor circuits connected to the through holes in the multilayer core substrate. Therefore, since this results in signal delay, it is thought that parasitic capacitance of the through holes increases.

A wiring substrate according to an embodiment of the present invention includes a multilayer core substrate and a build-up layer. The multilayer core substrate is formed of a central insulating layer, a first-surface-side insulating layer, and a second-surface-side insulating layer, and has a through hole, inner-layer conductor layers, and surface-layer conductor layers. The first-surface-side insulating layer is formed of at least two insulating layers on the first-surface side of the central insulating layer. The second-surface-side insulating layer is formed of at least two insulating layers on the second-surface side of the central insulating layer. The inner-layer conductor layers include a first inner-layer conductor layer and a second inner-layer conductor layer, the first inner-layer conductor layer is formed on a first surface of the central insulating layer, and the second inner-layer conductor layer is formed on a second surface of the central insulating layer. The surface-layer conductor layers include a first surface-layer conductor layer and a second surface-layer conductor layer, the first surface-layer conductor layer is formed on an outermost layer of the first-surface-side insulating layer, and the second surface-layer conductor layer is formed on an outermost layer of the second-surface-side insulating layer. The through hole is formed between the first surface-layer conductor layer and the second surface-layer conductor layer, and is connected to both the first inner-layer conductor layer and the second inner-layer conductor layer. A component is positioned in the first-surface-side insulating layer.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a multilayer core substrate comprising a central insulating layer, a first-surface-side insulating layer, and a second-surface-side insulating layer;
a build-up layer formed on the multilayer core substrate such that the build-up layer is positioned on the first-surface-side insulating layer of the multilayer core substrate; and
a component accommodated in the multilayer core substrate such that the component is positioned in the first-surface-side insulating layer of the multilayer core substrate,
wherein the multilayer core substrate is formed such that the first-surface-side insulating layer includes a plurality of insulating layers on a first-surface side of the central insulating layer and that the second-surface-side insulating layer includes a plurality of insulating layers on a second-surface side of the central insulating layer, and the multilayer core substrate includes a plurality of conductor layers comprising a first inner-layer conductor layer formed on a first surface of the central insulating layer, a second inner-layer conductor layer on a second surface of the central insulating layer, a first surface-layer conductor layer formed on an outermost layer of the first-surface-side insulating layer, a second surface-layer conductor layer formed on an outermost layer of the second-surface-side insulating layer, and a through hole formed between the first surface-layer conductor layer and the second surface-layer conductor layer such that the through hole is connected to the first inner-layer conductor layer and the second inner-layer conductor layer.

2. The wiring substrate according to claim 1, wherein the multilayer core substrate is formed such that the inner-layer conductor layers and the surface-layer conductor layers satisfy T1<T2 where T1 is a thickness of the inner-layer conductor layers, and T2 is a thickness of the surface-layer conductor layers.

3. The wiring substrate according to claim 1, wherein the multilayer core substrate is formed such that the inner-layer conductor layers and the surface-layer conductor layers satisfy S1<S2 where S1 is a number of layers of the inner-layer conductor layers, and S2 is a number of layers of the surface-layer conductor layers.

4. The wiring substrate according to claim 2, wherein the multilayer core substrate is formed such that the inner-layer conductor layers and the surface-layer conductor layers satisfy S1<S2 where S1 is a number of layers of the inner-layer conductor layers, and S2 is a number of layers of the surface-layer conductor layers.

5. The wiring substrate according to claim 1, wherein the multilayer core substrate has a through-hole opening penetrating through the central insulating layer, the first-surface-side insulating layer, and the second-surface-side insulating layer, and the through hole of the multilayer core substrate includes an inner-wall conductor layer formed on an inner wall of the through-hole opening and a filler filling the through-hole opening.

6. The wiring substrate according to claim 1, wherein the first-surface-side insulating layer of the multilayer core substrate includes a first resin substrate, and the component is accommodated in an opening penetrating through the first resin substrate of the first-surface-side insulating layer.

7. The wiring substrate according to claim 1, wherein the component is an electronic component comprising at least one of a capacitor, an inductor, an IVR, and a semiconductor such that the component has an electrode surface and a non-electrode surface on a side opposite to the electrode surface and that the electrode surface of the component is facing the build-up layer.

8. The wiring substrate according to claim 1, wherein the multilayer core substrate includes a plurality of connection conductors formed in the first-surface-side insulating layer such that the connection conductors are connecting the component positioned in the first-surface-side insulating layer of the multilayer core substrate to portions of the first surface-layer conductor layer that are not directly connected to the through holes.

9. The wiring substrate according to claim 1, wherein the first-surface-side insulating layer of the multilayer core substrate includes a first resin substrate, the component is accommodated in an opening penetrating through the first resin substrate of the first-surface-side insulating layer, and the multilayer core substrate includes an embedding resin filling a gap formed between an inner surface of the opening and the component.

10. The wiring substrate according to claim 2, wherein the multilayer core substrate has a through-hole opening penetrating through the central insulating layer, the first-surface-side insulating layer, and the second-surface-side insulating layer, and the through hole of the multilayer core substrate includes an inner-wall conductor layer formed on an inner wall of the through-hole opening and a filler filling the through-hole opening.

11. The wiring substrate according to claim 2, wherein the first-surface-side insulating layer of the multilayer core substrate includes a first resin substrate, and the component is accommodated in an opening penetrating through the first resin substrate of the first-surface-side insulating layer.

12. The wiring substrate according to claim 2, wherein the component is an electronic component comprising at least one of a capacitor, an inductor, an IVR, and a semiconductor such that the component has an electrode surface and a non-electrode surface on a side opposite to the electrode surface and that the electrode surface of the component is facing the build-up layer.

13. The wiring substrate according to claim 2, wherein the multilayer core substrate includes a plurality of connection conductors formed in the first-surface-side insulating layer such that the connection conductors are connecting the component positioned in the first-surface-side insulating layer of the multilayer core substrate to portions of the first surface-layer conductor layer that are not directly connected to the through holes.

14. The wiring substrate according to claim 2, wherein the first-surface-side insulating layer of the multilayer core substrate includes a first resin substrate, the component is accommodated in an opening penetrating through the first resin substrate of the first-surface-side insulating layer, and the multilayer core substrate includes an embedding resin filling a gap formed between an inner surface of the opening and the component.

15. The wiring substrate according to claim 3, wherein the multilayer core substrate has a through-hole opening penetrating through the central insulating layer, the first-surface-side insulating layer, and the second-surface-side insulating layer, and the through hole of the multilayer core substrate includes an inner-wall conductor layer formed on an inner wall of the through-hole opening and a filler filling the through-hole opening.

16. The wiring substrate according to claim 3, wherein the first-surface-side insulating layer of the multilayer core substrate includes a first resin substrate, and the component is accommodated in an opening penetrating through the first resin substrate of the first-surface-side insulating layer.

17. The wiring substrate according to claim 3, wherein the component is an electronic component comprising at least one of a capacitor, an inductor, an IVR, and a semiconductor such that the component has an electrode surface and a non-electrode surface on a side opposite to the electrode surface and that the electrode surface of the component is facing the build-up layer.

18. The wiring substrate according to claim 3, wherein the multilayer core substrate includes a plurality of connection conductors formed in the first-surface-side insulating layer such that the connection conductors are connecting the component positioned in the first-surface-side insulating layer of the multilayer core substrate to portions of the first surface-layer conductor layer that are not directly connected to the through holes.

19. The wiring substrate according to claim 3, wherein the first-surface-side insulating layer of the multilayer core substrate includes a first resin substrate, the component is accommodated in an opening penetrating through the first resin substrate of the first-surface-side insulating layer, and the multilayer core substrate includes an embedding resin filling a gap formed between an inner surface of the opening and the component.

20. The wiring substrate according to claim 4, wherein the multilayer core substrate has a through-hole opening penetrating through the central insulating layer, the first-surface-side insulating layer, and the second-surface-side insulating layer, and the through hole of the multilayer core substrate includes an inner-wall conductor layer formed on an inner wall of the through-hole opening and a filler filling the through-hole opening.
